(19) United States
(12) Patent Application Publication
(10) Pub. No.: US 2026/0350266 A1
(43) Pub. Date: Nov. 5, 2026

(54) METHOD FOR VERTICAL INTEGRATION AND ANALYSIS OF SPATIAL MULTI-OMICS DATA

(71) Applicant: ASPECT ANALYTICS NV, Genk (BE)

(72) Inventors: Marc CLAESEN, Genk (BE); Nico VERBEECK, Genk (BE); Wanqiu ZHANG, Genk (BE)

(21) Appl. No.: 19/152,240

(22) PCT Filed: Feb. 2, 2024
(86) PCT No.: PCT/EP2024/052613

§ 371 Date: Jul. 30, 2025

(30) Foreign Application Priority Data
Feb. 2, 2023 (BE) 2023/5080

(51) Int. Cl. G06F 30/27

(52) U.S. Cl. CPC G06F 30/27

(57) ABSTRACT

The present invention concerns a method for analyzing biomolecular associations in vertically integrated spatial multi-omics data. The method integrates association analysis of matched readouts across sets of spatial readouts within a specific type of tissue, and then compares the results of such association analyses across different tissue types. By involving multiple readouts (classes of biomolecules) and providing a structured framework to investigate relationships between classes of biomolecules, the method permits obtaining deeper biological understanding compared to methods that are limited to a single readout.

### FIELD OF THE INVENTION

The present invention relates to a method for molecular analysis of biological samples.

### BACKGROUND

Prade et al. 2020 disclose a computational multimodal workflow for combining mass spectroscopy of metabolites with multiplex immunohistochemistry (IHC). The IHC images are co-registered to the coordinates of the mass spectra per pixel. Once co-registered, the staining images are scaled to match the resolution of the measurement and color values per pixel are used for the definition of regions or for pixel-accurate analyses of metabolic correlations or heterogeneity.

Bergholt et al. 2018 disclose a correlated heterospectral lipidomic (HSL) approach based on co-registered Raman spectroscopy, desorption electrospray ionization mass spectrometry (DESI-MS), and immunofluorescence imaging. Pixelwise co-registration of Raman spectroscopy and DESI-MS imaging generated a heterospectral map used to interrelate biomolecular structure and composition of myelin.

The methods disclosed by Prade et al. 2020 and Bergholt et al. 2018 are directed towards the analysis of a matched readouts with a single tissue type or class of readouts.

WO2022051546 discloses methods of identifying a cross-modal feature from two or more spatially resolved data sets. The method comprises the steps of registering the two or more spatially resolved data sets to produce an aligned feature image including said spatially aligned two or more spatially resolved data sets; and extracting the cross-modal feature from the aligned feature image. Alignment and further examination of the images is affine multi-resolution registration. Said multi-resolution registration is known to be sensitive to the quality of the initial transformation guess. If the initial estimate is far from the optimal transformation, the algorithm may converge to a local minimum rather than the global optimum. Furthermore, multi-resolution approaches have higher chance of loss of information, noise sensitivity, and overfitting.

The present invention targets at solving at least one of the aforementioned disadvantages.

### SUMMARY OF THE INVENTION

The present invention and embodiments thereof serve to provide a solution to one or more of above-mentioned disadvantages. To this end, the present invention relates to a method for analyzing biomolecular associations in vertically integrated spatial multi-omics data according to claim 1. First, an initial set of spatial readouts are typically obtained from one or more biological tissue sections. Often, multiple tissue sections are required because the desired analytical techniques cannot be used on the same sections, for example because a technique may destroy tissue or otherwise affect another technique intended to be used. The common case of using multiple sections mandates an appropriate approach to create a common spatial reference across tissue sections that enables determination of which readouts were performed in sufficiently equivalent areas in tissue. Depending on the application this could be the same cells/cell types/cell state, same functional tissue unit, same gross anatomical structure, etc. Therefore, the method includes a step of co-registration. Depending on the chosen analytical techniques, readouts may be performed at vastly different spatial scales, both in terms of the physical distance between individual data points within a single spatial omics experiment, as well as the surface area that is covered by each data point, which can range in the order of square nanometers to hundreds of square microns. The former difference in spatial scales, if applicable, is typically dealt with as part of the co-registration process. The method further includes a step of granularity matching, this permits creating data points that can reasonably be deemed equivalent across readouts, even when the surface area of data points is very different across readouts. These steps provide the input for a variety of downstream analyses, for example differential expression analysis of spatial relationships between matched readouts. By incorporating multiple readouts (i.e. classes of biomolecules), the method allows the detection of many more changes in pathway activity compared to other methods that are limited to a single readout.

Preferred embodiments of the device are shown in any of the claims 2 to 14. A specific preferred embodiment relates to an invention according to claim 8. claim 8 further extends the method of claim 1 analysis of spatial relationships between matched readouts across multiple sets of spatial readouts. This enables detecting changes in relationships between analytes across tissue types/instants, which further enables various downstream analyses (e.g. detecting differential pathways between tissue types, reaction of one or more tissues to a treatment or drug).

### DESCRIPTION OF FIGURES

The following description of the figures of specific embodiments of the invention is merely exemplary in nature and is not intended to limit the present teachings, their application or uses. Throughout the drawings, corresponding reference numerals indicate like or corresponding parts and features.

FIG. 1 presents the sub-method to create a matched data set between spatial readouts.

FIG. 2 schematically presents the method for analyzing biomolecular associations from different sets of spatial readouts.

FIG. 3 shows the data structure comprising matched readouts for the ST and MSI data.

FIG. 4 shows a pairwise spatial correlations for matched readouts (ST and MSI), as an example output of the association analysis.

### DETAILED DESCRIPTION OF THE INVENTION

The present invention concerns a method for analyzing biomolecular associations in vertically integrated spatial multi-omics data. This method permits differential expression analysis of spatial relationships between matched readouts across multiple tissue types. Detecting changes in relationships between analytes across tissue types enables various downstream analyses, such as detecting differentially expressed pathways between tissue types. By involving multiple readouts (classes of biomolecules), the method permits detecting many more changes in pathway activity compared to methods that are limited to a single readout (e.g. the combination of genes, proteins and lipids is far more informative than just proteins alone).

In this context, the term tissue is to be understood as a biological sample. Said biological sample may include, though not restricted to, plant material, cell cultures, organoids, xenografts, animal/human material, etc.

In this context, vertical integration denotes that the spatial multi-omics data sets relate to the same physical sample (e.g., consecutive sections taken from a single organ), which are then jointly analyzed. In this context, spatial multi-omics data sets and spatial readout sets are to be understood, respectively, as multiple spatial-omics readings and multiple spatial readouts.

Unless otherwise defined, all terms used in disclosing the invention, including technical and scientific terms, have the meaning as commonly understood by one of ordinary skill in the art to which this invention belongs. By means of further guidance, term definitions are included to better appreciate the teaching of the present invention.

As used herein, the following terms have the following meanings:

“A”, “an”, and “the” as used herein refers to both singular and plural referents unless the context clearly dictates otherwise. By way of example, “a compartment” refers to one or more than one compartment.

“Comprise”, “comprising”, and “comprises” and “comprised of” as used herein are synonymous with “include”, “including”, “includes” or “contain”, “containing”, “contains” and are inclusive or open-ended terms that specifies the presence of what follows e.g. component and do not exclude or preclude the presence of additional, non-recited components, features, element, members, steps, known in the art or disclosed therein.

Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the invention described herein are capable of operation in other sequences than described or illustrated herein.

The recitation of numerical ranges by endpoints includes all numbers and fractions subsumed within that range, as well as the recited endpoints.

Whereas the terms “one or more” or “at least one”, such as one or more or at least one member(s) of a group of members, is clear per se, by means of further exemplification, the term encompasses inter alia a reference to any one of said members, or to any two or more of said members, such as, e.g., any ≥3, 24, ≥5, ≥6 or ≥7 etc. of said members, and up to all said members.

Unless otherwise defined, all terms used in disclosing the invention, including technical and scientific terms, have the meaning as commonly understood by one of ordinary skill in the art to which this invention belongs. By means of further guidance, definitions for the terms used in the description are included to better appreciate the teaching of the present invention. The terms or definitions used herein are provided solely to aid in the understanding of the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In a first aspect, the invention provides a method for analyzing biomolecular associations in vertically integrated spatial multi-omics data, the method comprising the steps of:
obtaining a first set of at least two biological sample spatial readouts from at least one biological sample using at least one analysis platform for each readout; establishing a common spatial coordinate system between spatial readouts by means of co-registration;
creating a matched data set by granularity matching;
performing an association analysis between at least the spatial readouts;

After the step of establishing a common spatial coordinate system, the datapoint granularity of all spatial measurements is matched, said step including the sub-steps of finding data points with lowest granularity, finding higher granularity datapoints in other readouts which are overlapped by each of the lowest granularity data points, and aggregating and associating each group of overlapped higher granularity datapoints to the lowest granularity datapoint overlapping them. The method advantageously permits the creation of a co-registered and spot-matched data set, allowing the creation of a matched data set. In said matched data set, each data point contains information of all complementary readouts which can reasonably be assumed to stem from equivalent tissue areas (e.g., mRNA, proteins and lipids for each matched spot). This matched data set serves as a foundational data structure for many types of downstream analysis. In an embodiment, the step of obtaining a first set of at least two biological sample spatial readouts is carried out using at least two different analysis platforms for each readout.

Granularity represents the spatial scale at which a spatial readout is performed, both in terms of the physical distance between individual data points within a single spatial omics experiment, as well as the surface area that is covered by each data point, which can range in the order of square nanometers to hundreds of square microns.

In this context, the term data set or dataset is to be understood as any plurality of spatial readouts. The plurality of spatial readouts within a single data set are defined by a combination of at least four variables, these variables being the sample, the tissue type, the state (i.e. healthy or cancerous) of the tissue and time. Any of these four variables may vary or remain the same from readout to readout inside the same data set. For example, each readout within a data set may have been collected from a different tissue sample, said tissue being of the same type, ranging from healthy to advanced tumor, and collected at different time instants.

In an embodiment, before the step of performing the association analysis and after the step of matching the datapoint granularity of the set of spatial readouts, each matched spatial readout is stored in a data structure, said data structure being identical for all matched spatial readouts in the set. In this way, the correspondence between each datapoint of each matched readout and the datapoints of the other readouts in the same set are advantageously maintained. This facilitates further processing of the matched readouts.

Association analysis is performed to infer one or several measures of co-expression of a plurality of readouts, based on the matched spatial readouts. For each plurality of readouts, the association analysis may yield one or several quantitative values, e.g., the pair-wise spatial correlation between a gene and a lipid (single value) for all genes and proteins in the matched data set, or the parameters of a fitted statistical model of the joint distribution for each gene-lipid pair (multiple values).

In an embodiment, the results of the association analysis are stored as at least one matrix. This permits easy storing and a more efficient access of values when said values are, for example, point estimates. This type of data structure is also particularly suitable for data visualization and interpretation by human operators.

In an embodiment, the results of the association analysis are stored as a tensor. This type of data structure advantageously permits easy and efficient storing of more detailed information such as quantiles, confidence intervals, and other. This type of data structure is also particularly suitable for data visualization and interpretation by human operators. Tensors are especially useful when an association analysis yields multiple numbers, e.g.: correlation value plus some statistics about the distribution of correlation (which can be obtained, e.g., via bootstrap) plus rank distribution tests (e.g., Mann-Whitney, Kolmogorov-Smirnov, etc.)

In an embodiment, all spatial readouts in the same set of spatial readouts are obtained from a single section of each biological sample. In this way, the step of co-registering the readouts of a set i advantageously made easier.

In an embodiment, all spatial readouts in the same set of spatial readouts feature the same surface area for data points. In this way, the step of granularity matching of the readouts after spatial co-registration of a set is advantageously made easier.

In an embodiment, the association analysis data of each set of spatial readouts is further subjected to a downstream analysis. Said downstream analysis is carried out using the results of multiple association analyses carried out previously, the different association analyses corresponding, for example, to different functional regions/ healthy v tumor/dosed v undosed, etc.

In an embodiment, the spatial readouts in the same spatial readout set are obtained from at least two sections of each biological sample. In another embodiment, each spatial readout in the same set of spatial readout is obtained from a different section of the biological sample. In any embodiment where more than one section per biological sample is required in order to obtain all spatial readouts of a single set, said sections are, by preference, extracted from said sample as close to each other as possible, most preferably, said sections should be adjacent to each other.

In an embodiment, the method further includes the step of obtaining additional sets of spatial readouts, and performing for each set the step of co-registration, granularity matching and association analysis. By preference, the analysis platforms used to obtain the spatial readouts for each additional set are the same as those used for all other sets of spatial readouts. This permits the creation of association analysis for each set of readouts, which association analyses can advantageously be compared to each other.

By preference, each association analysis of each set of spatial readouts is be stored in identical data structures. This advantageously permits the automation of any further analysis steps such as but not limited to carrying out of association analysis between a group of association analysis of different sets. Said further analysis may be differential expression analysis, clustering, segmentation or others.

In an embodiment, each additional set of spatial readouts corresponds to a different area of a sample. In a further or another embodiment, each additional set of spatial readouts corresponds to a different time instance. In a further or another embodiment, each additional set of spatial readouts corresponds to a different sample. The possibility to collect additional readout sets from different areas, at different instants and/or different samples greatly extend the biological insights which can be obtained from spatial readouts. These new insights provide the means for, but are not limited to, biomarker and drug target discovery, identification of new pathways, improved therapeutics and patient stratification, precision medicine, etc.

The invention is further described by the following non-limiting examples which further illustrate the invention, and are not intended to, nor should they be interpreted to, limit the scope of the invention.

The present invention will now be described in more details, referring to examples that are not limitative.

### DESCRIPTION OF FIGURES AND EXAMPLES

With the goal of better illustrating the properties of the invention, the following presents, as an example and limiting in no way other potential applications, a description of a number of preferred applications of the method for analyzing biomolecular associations in vertically integrated spatial multi-omics data based on the invention, wherein:

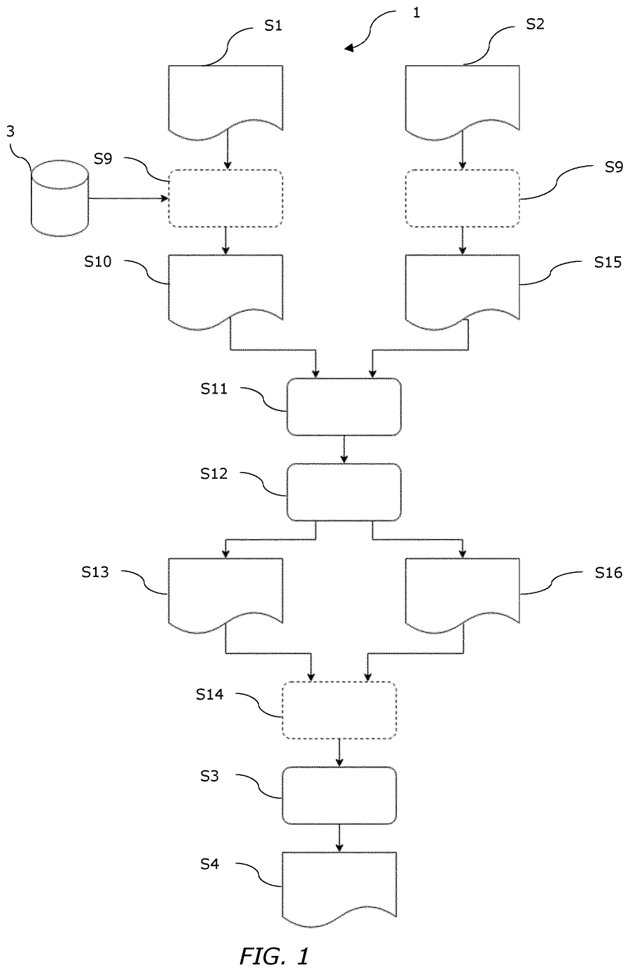

FIG. 1 presents the sub-method to create a matched data set between spatial readouts (1). The shown embodiment of the sub-method (1) starts with the collection of a first spatial readout of a first set of spatial readouts (S1) and a second spatial readout of a first set of spatial readouts (S2). After each of the steps of obtaining spatial readouts (S1, S2), each readout is optionally subject to a step of preprocessing (S9). Said preprocessing steps (S9) may include cleanup of data, transformation of data, annotation of the readouts, etc. A preprocessing step (S9) for the first set of spatial readouts (S1) may differ from another preprocessing step (S9) for the second set of spatial readouts (S2). In the shown embodiment of the sub-method (1), the preprocessing step (S9) of the first spatial readout includes the retrieval of information from a database (3). Said information may include previous annotated readouts which may serve as a basis for comparison with the first spatial readout, thereby permitting, for example, automatic annotation of said first spatial readout (e.g. identification of MSI peaks via LC-MS) and augmenting the information of the first spatial readout (e.g. augmenting spatial transcriptomics data with scRNAseq). After the step of preprocessing (S9), a preprocessed spatial readout file (S10, S15) is created for each spatial readout, which preprocessed spatial readout files (S10, S15) are used as input in a co-registration step (S11). In the case that one or more steps of preprocessing (S9) are omitted, the spatial readout for which preprocessing was omitted is used as input of the co-registration step (S11) instead of the pre-processed spatial readout file. In the present embodiment, the co-registration step (S11) establishes a common coordinate system between the preprocessed spatial readout files (S10, S15) before the step of granularity matching (S12). The step of granularity matching (S12) yields a matched first spatial readout (S13) file and a matched second spatial readout (S16) file, which files may, optionally, be preprocessed (S14) before performing an association analysis (S3). Said preprocessing of the matched readouts (S14) may entail, for example, batch effect removal, and can be based on either one of the matched spatial readouts (S13, S16) and/or the combination of both (e.g. by using joint embeddings/deep learning algorithms). After the association analysis (S3) an association analysis data structure is generated (S4).

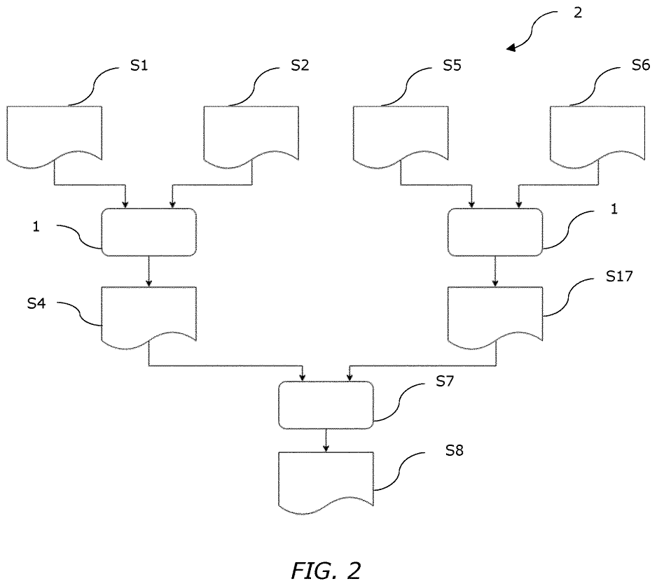

FIG. 2 schematically presents the method for analyzing biomolecular associations from different sets of spatial readouts (2). The method (2) includes the processing with the execution of the sub-method to create and analyze matched data set between spatial readouts (1) for each set of collected spatial readouts. The figure shows a first set of redouts (S1, S2) and a second set of spatial readouts (S5, S6). In this example S1 and S5 are equivalent spatial readouts on different tissue regions and the same is true for S2 and S6. Each set is processed using the sub-method to create and analyze matched data set between spatial readouts (1) resulting in the production of an association analysis data structure for each set of readouts (S4, S17), which data structures are used for a downstream analysis (S7). In the shown embodiment, the steps of co-registration (S11) and granularity matching (S12) were carried out for all the obtained spatial readouts (S1, S2, S5 and S6) during the execution of the sub-method (1) for each set of spatial readouts. In this way the association analysis data structure of the first set of readouts (S4) and the association analysis data structure of the second set of readouts (S17) are already co-registered and matched in granularity relative to each other.

The present invention will now be further exemplified with reference to the following examples. The present invention is in no way limited to the given examples or to the embodiments presented in the figures.

Example 1 relates to a specific implementation example of the sub-method disclosed in FIG. 1. The example shows the integration of spatial transcriptomics and spatial lipidomics. In this example, Mass Spectrometry Imaging (MSI) is used for lipid imaging of a first of two serial sections with 20 micron vertical distance between each other. This MSI image is the first spatial readout (S2). Spatial Transcriptomics (ST) is used to acquire a second spatial readout (S1) from the second section. In this example, the vertical distance between sections was very advantageously limited in order to minimize the probability of having different cell types at corresponding regions in both sections.

MSI and ST data from the set of readouts of the first section (S1, S2) are preprocessed (S9) using conventional practice approaches per readout (S1, S2). The preprocessing (S9) of each readout (S1 and S2) included steps of data normalization, filtering, feature extraction, realignment (for the MSI data). Additionally, the ST data (S1) is deconvolved using information obtained from single cell RNA sequencing on bulk samples, thereby augmenting the preprocessed ST readout (S10) beyond the original ST readout included in S1.

Co-registration (S11) between the lipid imaging (S2) and spatial transcriptomics data (S1) was done by co-registering both modalities to a third microscopy image which was haematoxylin and eosin (H&E) stained. The preprocessed lipid imaging (S15) and preprocessed spatial transcriptomics data (S10) are indirectly registered to each other, by combining the registrations of MSI with microscopy and ST with microscopy data. This approach of co-registering (S11) multiple sections via one proxy section is inevitable in applications involving more than two sections, in which typically all spatial readouts are co-registered (S11) with a readout that is somewhere in the middle of the vertical stack of sections.

Pathologist annotations of various tissue types were provided on the microscopy data included, including healthy tissue and various grades of tumor. The regions annotated by pathologists are transferred to the spatial readouts after co-registration (S11) with microscopy. Each tissue type as annotated by pathologists gives rise to one set of spatial readouts (e.g., tumor grade A, which contains a number of spots/pixels in MSI and ST data).

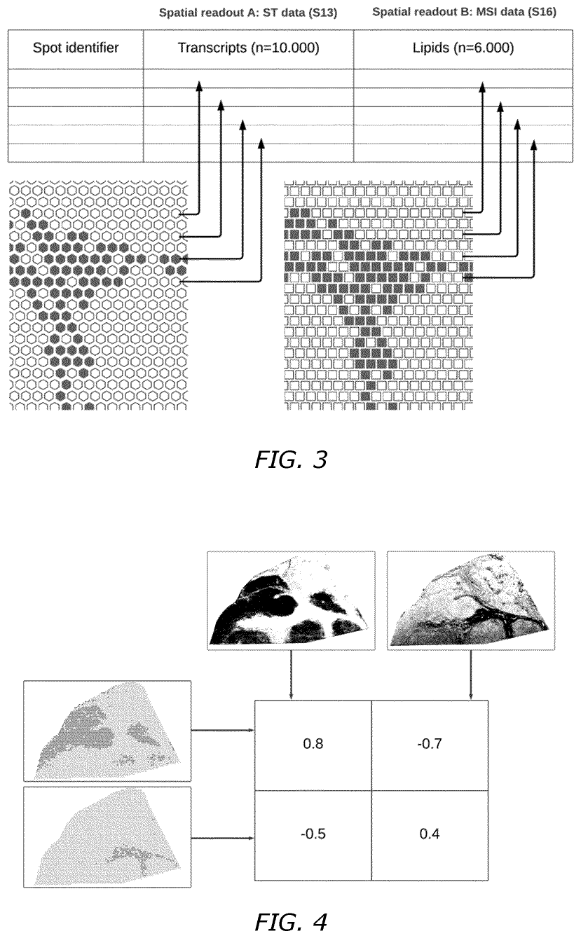

After co-registering (S11) the MSI and ST data (using the H&E microscopy image as proxy), the difference in spatial readout scale and size is accounted for by granularity matching (S12). In this example, the MSI data was acquired at spatial resolution (pixel size) of 30 microns, whereas the ST data was obtained using the Visium platform, which features spot diameters of 55 microns. The granularity of both spatial readouts was matched (S12) by applying Gaussian smoothing to MSI pixels close to each ST spot to obtain a representative aggregate lipid spectrum associated with each ST spot, i.e., the matched spatial readouts for MSI and ST (S13 and S16). In order to exemplify a data structure for storing and representing matched spatial readouts for MSI and ST (S13 and S16), FIG. 3 shows data structure comprising matched readouts for the ST (S13) and MSI data (S16). This data structure can be thought of as a data frame, where each row represents a single matched spot in the set of spatial readouts, and each column contains the information of one individual feature (organized per readout, here RNA transcripts and lipids).

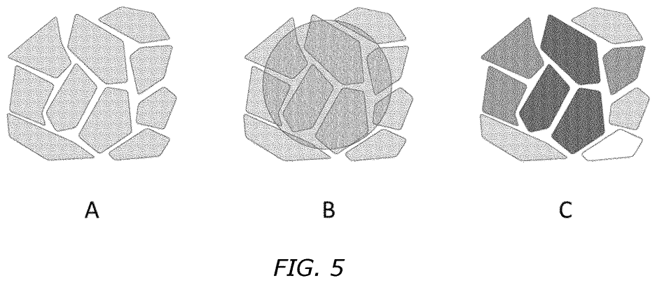

Pairwise associations between the matched spatial readouts (S3) were then computed by calculating the spatial correlation between gene and lipid expressions, for all genes and lipids in the matched spatial readouts (S13 and S16), thus yielding a correlation matrix comprising the correlation value for each gene-lipid pair within each set matched spatial readouts S13 and S16 (tissue types). In order to illustrate such a correlation matrix and the data contained therein, a very simplified example is provided in FIG. 4. The figure shows the output of the association analysis (S4) as pairwise spatial correlations for matched readouts (ST and MSI) (S13 and S16) represented by numerical values.

Finally, a differential expression analysis was performed between tissue types, e.g., between healthy and tumor tissue, to identify whether any gene-lipid correlations change in a significant way between tissue types (healthy vs. tumor). For this purpose, pathologist annotations of various tissue types were provided on the microscopy data included, including healthy tissue and various grades of tumor. The regions annotated by pathologists are transferred to the spatial readouts after co-registration (S11) with microscopy. Each tissue type as annotated by pathologists gives rise to one set of spatial readouts (e.g., tumor grade A, which contains a number of spots/pixels in MSI and ST data). This allows for a downstream analysis (S7) between different sets of spatial readouts to be carried out. Using this approach, a set of changes in correlation were identified, i.e., pairs of genes and lipids which are spatially co-expressed in healthy tissue that are no longer spatially co-expressed in tumor tissue (and vice versa). Such insights are of biological significance, as they provide a strong indication of change in underlying biology, and provide a good starting point for further investigation (e.g., pathway analysis starting from the known gene and lipid).

Example 2 relates to the application of the method according to the invention wherein spatial readout sets are acquired at different time points after dosing equivalent model animals with a drug of interest. An example set of readouts could be mass spectrometry imaging (to localize drug metabolites) and spatial transcriptomics (to investigate changes on the transcriptome level), which are typically performed on serial sections and at different spatial resolution, thus necessitating both co-registration and granularity matching (S11, S12). Using spatial correlation as an association analysis (S3), one can identify gene expressions that are associated with the presence or absence of a certain drug and/or its metabolites within a set of spatial readouts (i.e., one time point after dosing). By analysing a plurality of sets of spatial readouts (corresponding to different time points after dosing the animals) (S1, S2 and S5, S6), a downstream analysis (S7) is carried out to determine the time-based effects of a drug metabolite on transcriptomics expressions.

An example application involves a single biopsy which contains multiple tissue types. Such tissue types could, for example, be determined by pathologist annotations which assign one of several tumour grades to specific regions within a tissue. Each annotated tissue type gives rise to a set of spatial readouts stemming from the same original biopsy. In this example application, one may have plurality of tissue types (e.g., multiple cancer grades), thus giving rise to an equivalent amount of sets of spatial readouts. Example readouts r for such an application could be immunohistochemistry, lipid imaging via mass spectrometry and spatial transcriptomics. Using spatial correlation for association analysis enables identifying which lipids and genes are co-expressed within each tissue type (set of spatial readouts). These lists of co-expressed lipids and genes can then be compared across tissue types (sets of spatial readouts) using common exploratory bioinformatics methods, for example via dimensionality reduction via linear or nonlinear embeddings (e.g., PCA, UMAP, NMF, t-SNE, etc.) or clustering approaches (e.g., k-means, DBSCAN, etc.) to identify which tissue types exhibit comparable associations between genes and lipids (e.g., tumor grades A and B are similar to each other but different from grades C and D).

Many data analysis workflows do not use the original raw readouts (S1, S2, S5, S6), but instead work on some transformed readouts or insights otherwise derived from the raw readouts by preprocessing (S9) said raw readouts(S1, S2, S5, S6). An example of a derived insight is creating a vector embedding which captures tissue morphology via deep learning starting from a high resolution microscopy image (e.g., using convolutional neural networks). In further analysis (S10 and beyond), the vector embeddings can then be used instead of and/or in conjunction with the pixel values of the microscopy image.

Another class of transformed readouts (S9) are approaches that augment the original spatial readouts with additional information (3). A first example of such augmented readouts includes annotating peaks in mass spectrometry imaging based on identifications obtained via database searches and/or concomitant experiments (e.g., liquid chromatography mass spectrometry). Another example is augmenting or deconvolving spatial transcriptomics data with information obtained from bulk single cell analysis such as scRNAseq, in which information on unmeasured genes in the spatial transcriptomics readouts is imputed based on cell type and the expression of those cell types as observed in the single cell data. A third example is the use of an anatomical atlas to enrich spatial readouts with anatomical labels and/or additional information that is embedded within the atlas. This can be achieved by mapping a tissue sample to a matching tissue section in such an atlas, and transferring the labels in the atlas to the tissue sample. This anatomical atlas can also serve as a common reference frame, and intermediary for the registration of different tissue sections. For example, the Allen Mouse Brain Atlas (AMBA) can be used as a reference to register sections measured in the mouse brain using different modalities. The AMBA contains anatomical labels for the different regions of the mouse brain, along with spatial omics measurements and data originating from various biomedical imaging modalities. This information can be integrated to augment the spatial readouts during preprocessing (S9), in which case the atlas is used as an external database (3).

Granularity matching (S12) can be performed in various ways. A simple approach is to identify reasonably corresponding individual data points between readouts via spatial nearest neighbors. More complex approaches for granularity matching (S12) could create a meaningful combination of data points in the readout of highest spatial resolution to create a representative aggregate readout that corresponds to the readout at lowest spatial resolution, as in the example 1.

Another approach for granularity matching (S12) is to extract a statistic for the matching spot regions, such as the mean or median expression or the density of expression of the readout and use this to match readouts at different granularities.

Many approaches can be used for association analysis (S3). A simple example would be to compute point estimates of an appropriate spatial association measure, such as a (spatial) correlation coefficient. This yields a tabular data structure (e.g., a matrix) comprising the point estimate of the statistic between pairs of readouts. Instead of using a single point estimate, one could also estimate a confidence interval or other parameters of the correlation between pairs of readouts, thus yielding a multi-dimensional tabular data structure (e.g., a tensor).

In many cases, the association analysis would operate pairwise between individual features across two readouts (e.g., computing spatial correlation between one gene and one lipid when combining lipid imaging and spatial transcriptomics). However, in other applications, the association analysis (S3) could cover multiple features per readout (e.g., modelling the joint distribution of multiple genes and multiple lipids based on the matched spatial readouts) and/or more than two readouts (e.g., spatial proteomics, lipidomics and transcriptomics).

An association Analysis (S3) can also be performed by first conducting a dimensionality reduction method such as principal component analysis or nonnegative matrix factorization on each of the different modalities (as preprocessing S14), for all samples combined or each sample separately. This extracts associated analyte subsets per modality. A method such as canonical correlation analysis is then used to link the extracted subsets across modalities.

An association analysis (S3) can be performed by mapping analytes directly onto biochemical pathways. One or more biochemical pathways, extracted from a database, constructed from a number of different databases, or from other prior knowledge sources are used to cluster together analytes across modalities. Expression per analyte in the pathway can then be used to directly differentiate biological response between tissue regions within a single section and/or tissue regions between different samples.

An important observation is that the final output of our invention yields novel insights that can inform further downstream analysis. For example, following the workflow described in detail earlier to determine differential correlations across tissue types between genes and lipids (based on spatial transcriptomics and lipid imaging using mass spectrometry imaging, respectively), a key insight that can be obtained is a set of genes and lipids that co-express in healthy tissue but not in cancer. The genes and lipids whose spatial correlations are identified to be differentially expressed across tissue types can be used as inputs for various forms of pathway analysis to get a deeper understanding of the underlying biology, and potentially uncover which biological pathways might be affected in cancer tissue.

A further application example of the application of the method according to the present invention relates return to normalcy analysis. Return to normalcy in the pharma use case refers to the situation where a drug compound is administered to a diseased organism, and the user wants to evaluate whether the detected biochemical signals have shifted from the diseased state to the biochemical signals observed in the healthy state, which would indicate that the drug has had a positive effect.

Starting from a wild type, WT, model, a disease model and a disease model dosed with a new drug compound. The samples are subjected to multi-modal measurements, e.g. a spatial transcriptomics dataset and a protein-focused dataset for each model. Then, spatial registration of the two (or more) datasets is carried out per measured organism, followed by a step of granularity matching. The molecules across both datasets are then correlated in order to construct an association analysis data structure in the form a correlation matrix for each of the three models. The distances are then computed between the correlation matrix (or part thereof) of the WT, disease model, and disease model dosed with a new drug compound. This permits assessing if the distance between the WT and dosed model has reduced compared to the distance between the disease model and the WT model.

In a study where different drug doses and/or different drugs with a similar intended goal are tested, the impact of different doses and/or different drugs can be assessed using this approach. Association analysis data structures, such as a correlation matrix, kernel matrix, tensor or set of correlation matrices and/or kernel matrices and/or tensors can be stored in a database for a particular organism, tissue and/or biological state (healthy, disease,. These sets of correlating molecules can be used as reference points to compare newly acquired data. This database can be leveraged for several purposes, e.g. for quality control (is a newly measured healthy sample comparable to historically measured samples), for return to normalcy as described above, for retrieval of drug-induced reactions,.

Prior to calculation of the association analysis data structure, spot locations can be grouped together based on cell-segmentation or tissue segmentation algorithms. Here, similar segments can be grouped together based on specific markers (e.g. cell typing). An association analysis data structure can then be calculated per segment or segment group. The resulting association analysis data structures can then be compared in order to retrieve differential cell-or tissue-specific association-pairs. This allows the user to find differences in co-expression between cell types. Likewise, the resulting association analysis data structures can be stored in a database as reference points for a specific cell-type or tissue type in a certain state, in a similar way as described above.

The resulting association analysis data structures can be used to investigate cell or tissue trajectories, i.e. to study transition from one cell or tissue state to another, where minor differences between the association analysis data structures of cell or tissue segments are mapped as intermediate states between the two cell or tissue states.

An association analysis data structure can be calculated per spot or per cell. These association analysis data structures can be clustered together with a clustering algorithm (DBSCAN, Leiden clustering, Louvain clustering) with or without a prior dimensionality reduction (UMAP, t-SNE,. The resulting clusters can be used to group spots in the spatial data (e.g. cell types, tissue regions).

Not all molecules can be readily targeted by drug compounds, and for this reason drug compounds are often proteins or RNA molecules. Proteins and RNA molecules can offer suitable binding sites with which a drug can interact, which results in e.g. inhibition of the protein. By using sets of correlated molecules, extracted from the association analysis data structure, a suitable drug target can be extracted based on an identified molecule of interest. For example, when a lipid is observed to be differentially expressed in a healthy versus a diseased organism, the proteins correlating with this lipid can be extracted as potential drug targets.

In such a setting, the user applies the pipeline to calculate an association analysis data structure per organism and/or state. By performing a differential analysis of the resulting association analysis data structures, the association-pairs that are differentially expressed between the different states can be extracted. This differential can involve calculation of differences over multiple technically and/or biologically replicated experiments in order to gain statistically robust results. The differential analysis provides the molecules of interest that are likely involved in the underlying pathomechanisms of the disease under study. By examining the sets of molecules that correlate with the differentially expressed association-pairs, related potential drug targets can be extracted.

Furthermore, the molecules of interest, together with their correlating molecules can be mapped to known biological pathways. Using these pathways, other potential drug targets can be identified.

In yet another application example, a multi-omic pipeline according to the present invention can be applied to discover biomarkers, i.e. to find molecules which signal a certain disease state. Once a biomarker has been identified, a stain or antibody can be developed to readily detect this biomarker in e.g. a diagnostic setting. However, not all molecules can be readily targeted by stains or antibodies, or cannot be targeted with a high specificity. Proteins and RNA molecules are often more readily detectable than lipids.

In order to find such suitable, detectable biomarkers, a workflow analogous to that described in retrieving related drug targets can be used.

By using sets of correlated molecules, extracted from the association analysis data structure, a suitable biomarker can be extracted based on an identified molecule of interest. For example, when a lipid is observed to be differentially expressed in a healthy versus a diseased organism, the proteins correlating with this lipid can be extracted as potential biomarkers.

In such a setting, the user applies the pipeline to calculate an association analysis data structure per organism and/or state. By performing a differential analysis of the resulting association analysis data structures, the association-pairs that are differentially expressed between the different states can be extracted. This differential can involve calculation of differences over multiple technically and/or biologically replicated experiments in order to gain statistically robust results. The differential analysis provides the molecules of interest that are potentially involved in the underlying pathomechanisms of the disease under study. By examining the sets of molecules that correlate with the differentially expressed association-pairs, related potential biomarkers can be extracted.

Furthermore, the molecules of interest, together with their correlating molecules can be mapped to known biological pathways. Using these pathways, other potential biomarkers can be identified.

Doing granularity matching starts from readouts with a potentially complex spatial footprint may require a variety of strategies. Such complex spatial footprints for individual readouts are not uncommon, such as segmented cells or polygon-shaped readouts like GeoMx or laser-capture microdissected regions. This particularly highlights that, while spatial smoothing is a rudimentary form of spot matching, the general procedure can be significantly more informed.

FIG. 5 illustrates a complex granularity matching example, wherein readouts are matched for segmented cells to a circular capture area from another assay (for example Visium). Depending on the application, many approaches can be used to perform such complex matching, for instance by weighing the cell readouts based on the overlap of their capture area with the circular spot. Another approach would be to average the readouts of cells for which the majority of associated capture area is contained within the circular spot, etc. Part A of the figure depicts segmented cells, which are then matched to a circular readout from a parallel assay (e. g, Visium), as shown in part B. Part C shows the weighted readout contribution per cell for the matched result.

Overall, the design of an appropriate granularity matching scheme is a critical step in creating an integrated (matched) spatial multi-omics data structure. The illustration in FIG. 5 depicts how granularity matching can be done from the assay with more granular spatial footprints to the less granular one, but granularity matching procedures that work the other way around can also be devised.

One other way of performing the granularity matching step is by using cell-segmented data as a starting point. Here, cell segmentation, ie. the delineation of cell boundaries based on the spatial readouts and subsequent segmentation of the image into individual cells based on this delineation, is performed on one or more of the spatial readouts as a preprocessing and annotation step. The association analysis is then performed on the level of cells, namely the resulting cell types, cell states or aggregated analytical content on the cell level.

Cells are the functional units and building blocks that are used for reasoning in spatial biology, where each cell's state, including its type, structure, and molecular content, plays a critical role in its functionality and interaction within the larger biological system. Through association analysis across multiple spatial omics readouts, cell types and states can be better characterized and new cell types and states can be identified. The resulting association analysis data structures (in this case cell-based) can be used to create cell-level databases of healthy and diseased samples, identify disease states, screen novel drug targets, and evaluate return to normalcy.

Understanding the interplay between different cells within a region of interest is crucial in determining biological functioning of an organism and gaining insights into the patho-mechamisms of a disease. As such, analyzing and comparing cell contents, cell type densities and cell type counts in spatially localized regions, commonly referred to as neighborhood analysis, are often included in spatial omics data analysis based on individual omics modalities. Using the presented workflow, neighborhood analysis algorithms can be used as a type of association analysis, where they are reinforced by the combined spatial readout across different omics modalities. Furthermore, incorporation of additional spatial omics readouts can aid in cell deconvolution, i.e. to improve determination of the proportions of cell types or states within a measured region of interest.

### LIST OF NUMBERED ITEMS

1 sub-method to create and analyze matched data set between spatial readouts
2 method for analyzing biomolecular associations from different sets of spatial readouts
3 database
S1 first spatial readout of first set
S2 second spatial readout of first set
S3 association analysis
S4 association analysis data structure
S5 first special readout of second set
S6 second special readout of second set
S7 downstream data analysis
S8 downstream data analysis data structure
S9 preprocessing
S10 preprocessed special readout
S11 co-registration
S12 granularity matching
S13 matched spatial readout
S14 preprocessing of matched spatial readout
S15 preprocessed special readout
S16 matched spatial readout
S17 association analysis data structure of the second set of readouts

The present invention is in no way limited to the embodiments shown in the figures nor by the disclosed examples. On the contrary, methods according to the present invention may be realized in many different ways without departing from the scope of the invention.

1. A method for analyzing biomolecular associations in vertically integrated spatial multi-omics data, the method comprising:
obtaining a first set of at least two biological sample spatial readouts from at least one biological sample using at least one analysis platforms for each readout;
establishing a common spatial coordinate system between spatial readouts by means of co-registration;
creating a matched data set by granularity matching; and
performing an association analysis between at least the matched spatial readouts;
characterized in that, after the establishing a the common spatial coordinate system, matching datapoint granularity of all spatial measurements, said matching including finding data points with lowest granularity, finding higher granularity datapoints in other readouts which are overlapped by each of the lowest granularity data points, and aggregating and associating each group of overlapped higher granularity datapoints to the lowest granularity datapoint overlapping them.

2. The method according to claim 1, characterized in that, before the performing the association analysis and after the step of matching the datapoint granularity of the set of spatial readouts, each matched spatial readout is stored in a data structure spatially referenced to each data structure of all the other spatial readouts.

3. The method according to claim 1, characterized in that, results of the association analysis are stored as at least one matrix.

4. The method according to claim 1, characterized in that, results of the association analysis are stored as a tensor.

5. The method according to claim 1, characterized in that, all spatial readouts in the same set of spatial readout are obtained from a single section of the at least one biological sample.

6. The method according to claim 1, characterized in that, the spatial readouts in the same set of spatial readout are obtained from at least two sections of the at least one biological sample.

7. The method according to claim 6, characterized in that, each spatial readout in the same set of spatial readout is obtained from a different section of the at least one biological sample.

8. The method according to claim 1, characterized in that, the method further includes obtaining additional sets of spatial readouts, and performing for each set co-registration, granularity matching, and association analysis.

9. The method according to claim 8, characterized in that, the association analysis data of each set of spatial readouts is further subjected to a downstream analysis.

10. The method according to claim 8, characterized in that, the analysis platforms used to obtain the spatial readouts for each additional set are the same as those used for all other sets of spatial readouts.

11. The method according to claim 1, characterized in that, all spatial readouts in the same spatial readout set feature the same surface area for data points.

12. The method according to claim 8, characterized in that, each additional set of spatial readouts corresponds to a different area of a sample.

13. The method according to claim 8, characterized in that, each additional set of spatial readouts corresponds to a different time instance.

14. The method according to claim 8, characterized in that, each additional set of spatial readouts corresponds to a different sample.
